(19) United States
(12) Patent Application Publication
(10) Pub. No.: US 2025/0309001 A1
(43) Pub. Date: Oct. 2, 2025

(54) METALLIZATION AND PLANARIZATION

(71) Applicant: Tokyo Electron Limited, Tokyo (JP)

(72) Inventors: Emilia HIRSCH, Albany, NY (US); Peng WANG, Albany, NY (US)

(73) Assignee: Tokyo Electron Limited, Tokyo (JP)

(21) Appl. No.: 18/619,755

(22) Filed: Mar. 28, 2024

(51) Int. Cl. H01L 21/66; G01R 31/305; H01L 21/3105; H01L 21/67

(52) U.S. Cl. CPC H01L 22/12; G01R 31/305; H01L 21/31053; H01L 21/67288

(57) ABSTRACT

A method of defect detection includes providing a wafer including an insulating layer formed over a conductive layer. An opening is formed in the insulating layer by an etch process. A metal material is deposited in the opening and then etched to form a recess in the insulating layer so that a top surface of the metal material is below a top surface of the insulating layer. The wafer is polished so that the top surface of the metal material and the top surface of the insulating layer are co-planar. The wafer is characterized by electron beam inspection in voltage contrast mode to determine whether a defect of the etch process exists. The defect exists when a VC signal of the opening is below a threshold, and the defect does not exist when the VC signal of the opening is at or above the threshold.

### FIELD OF THE INVENTION

This disclosure relates generally to a method of microfabrication and more specifically to metallization and planarization. This disclosure also relates generally to a method of defect detection and more specifically to etch and/or fill defect inspection.

### BACKGROUND

In the manufacture of a semiconductor device (especially on the microscopic scale), various fabrication processes are executed such as film-forming depositions, etch mask creation, patterning, material etching and removal, and doping treatments. These processes are performed repeatedly to form desired semiconductor device elements on a substrate.

### SUMMARY

The present disclosure relates to a method of microfabrication and a method of defect detection.

According to a first aspect of the disclosure, a method of microfabrication is provided. The method includes providing a wafer including a conductive layer and an insulating layer formed over the conductive layer. An opening is formed through the insulating layer to expose the conductive layer. A metal material is deposited to fill the opening. The metal material is etched to form a recess in the insulating layer so that a top surface of the metal material is below a top surface of the insulating layer. The wafer is polished so that the top surface of the metal material and the top surface of the insulating layer are co-planar.

In some embodiments, the polishing includes executing a chemical-mechanical polishing (CMP) process of the insulating layer.

In some embodiments, the CMP process is configured to stop at the top surface of the metal material.

In some embodiments, a dielectric material is deposited to fill the recess and cover the insulating layer.

In some embodiments, the polishing includes executing a chemical-mechanical polishing (CMP) process of the dielectric material and the insulating layer.

In some embodiments, the CMP process is configured to stop at the top surface of the metal material.

In some embodiments, the dielectric material includes silicon oxide, silicon nitride, silicon oxynitride, silicon carbonitride, silicon carbon oxynitride or a combination thereof.

In some embodiments, the dielectric material and the insulating layer include different dielectrics.

In some embodiments, the dielectric material and the insulating layer include a same dielectric.

In some embodiments, the wafer further includes an etch stop layer (ESL) formed between the conductive layer and the insulating layer.

In some embodiments, a first etch process of the insulating layer is executed that stops at the ESL to form the opening through the insulating layer.

In some embodiments, a second etch process of the ESL is executed via the opening to expose the conductive layer.

In some embodiments, the metal material includes ruthenium.

In some embodiments, the metal material does not include copper.

In some embodiments, the conductive layer and the metal material include different metals.

In some embodiments, the insulating layer includes silicon oxide, silicon nitride, silicon oxynitride, silicon carbonitride, silicon carbon oxynitride or a combination thereof.

In some embodiments, the opening has a lateral dimension of 8-20 nm. The opening has a depth of 30-90 nm. The recess has a depth of 1-10 nm.

According to a second aspect of the disclosure, a method of defect detection is provided. The method includes providing a wafer including a conductive layer and an insulating layer formed over the conductive layer. An opening is formed in the insulating layer by an etch process. A metal material is deposited in the opening by a deposition process. The metal material is etched to form a recess in the insulating layer so that a top surface of the metal material is below a top surface of the insulating layer. The wafer is polished so that the top surface of the metal material and the top surface of the insulating layer are co-planar. The wafer is characterized by electron beam inspection (EBI) in voltage contrast (VC) mode to determine whether a defect of the etch process exists. The defect exists when a VC signal of the opening is below a threshold, and the defect does not exist when the VC signal of the opening is at or above the threshold.

In some embodiments, the VC signal includes brightness of the metal material in an EBI VC image. The defect exists when the brightness of the metal material is below a brightness threshold. The defect does not exist when the brightness of the metal material is at or above the brightness threshold.

In some embodiments, the defect exists when the metal material does not completely fill the opening by the deposition process. The defect does not exist when the metal material completely fills the opening by the deposition process.

In some embodiments, the defect exists when the opening is not etched through the insulating layer by the etch process. The defect does not exist when the opening is etched through the insulating layer by the etch process.

Note that this summary section does not specify every embodiment and/or incrementally novel aspect of the present disclosure or claimed invention. Instead, this summary only provides a preliminary discussion of different embodiments and corresponding points of novelty. For additional details and/or possible perspectives of the invention and embodiments, the reader is directed to the Detailed Description section and corresponding figures of the present disclosure as further discussed below.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be increased or reduced for clarity of discussion.

FIG. 1 shows a flow chart of a process of microfabrication, in accordance with some embodiments of the present disclosure.

FIGS. 2, 3, 4, 5, 6, 7 and 8 show vertical cross-sectional views of a wafer at various intermediate steps of manufacturing, in accordance with some embodiments of the present disclosure.

FIG. 9 shows a flow chart of a process of defect detection, in accordance with some embodiments of the present disclosure.

FIGS. 10 and 11 show vertical cross-sectional views of a wafer at various intermediate steps of manufacturing, in accordance with some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a feature over or on a second feature in the description that follows may include embodiments in which the and second features are formed in direct contact, and may also include embodiments in which additional features may be formed between the and second features, such that the and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed. Further, spatially relative terms, such as “top,” “bottom,” “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The order of discussion of the different steps as described herein has been presented for clarity's sake. In general, these steps can be performed in any suitable order. Additionally, although each of the different features, techniques, configurations, etc. herein may be discussed in different places of this disclosure, it is intended that each of the concepts can be executed independently of each other or in combination with each other. Accordingly, the present invention can be embodied and viewed in many different ways.

In the drawings, like reference numerals designate identical or corresponding parts throughout the several views. Additionally, as used herein, the words “a”, “an” and the like generally carry a meaning of “one or more”, unless stated otherwise.

Furthermore, the terms, “approximately”, “approximate”, “about” and similar terms generally refer to ranges that include the identified value within a margin of 20%, 10%, or preferably 5%, and any values therebetween.

Planarization is a technique that planarizes, flattens or smooths a wafer surface topography for example by filling in recessed areas (e.g. trenches, holes, slits, vias, etc.), etching elevated areas (e.g. protruding portions, excessive material deposition), or a combination of both. Planarization is a critical process in semiconductor manufacturing that smooths irregularities on wafers. Chemical-mechanical polishing (CMP), also known as chemical-mechanical planarization, is the dominant technique for achieving wafer planarity in the semiconductor industry nowadays. CMP involves both chemical reactions and mechanical polishing and therefore smooths surfaces with a combination of chemical and mechanical forces.

As semiconductor devices continue to shrink, copper (Cu) metallization has got its own challenges and is becoming more difficult and elusive, especially when the contact critical dimension (CD) is in the sub-10 nm regime. Ruthenium (Ru) metal filling is promising in replacing Cu for contact metallization. However, CMP of Ru is not mature or well established due to the material hardness of Ru.

Techniques herein provide a method for Ru metallization that bypasses Ru CMP, i.e. planarizing the newly formed Ru surface without the need for Ru CMP. The method herein can employ a known CMP process of a common material (e.g. silicon oxide) to bypass Ru CMP. The endpoint of CMP could be enabled to improve process robustness. The method can be used for metallization of contact holes. Additionally, techniques herein can enable defect inspection for contact etch processes especially when the CD is sub-10 nm. The Ru metallization flow disclosed herein can enable contact defect inspection to improve process and tool capability. Moreover, techniques herein can be utilized for electron beam inspection (EBI) defect inspection in voltage contrast (VC) mode to improve contact etch process and evaluate tool capability for these processes.

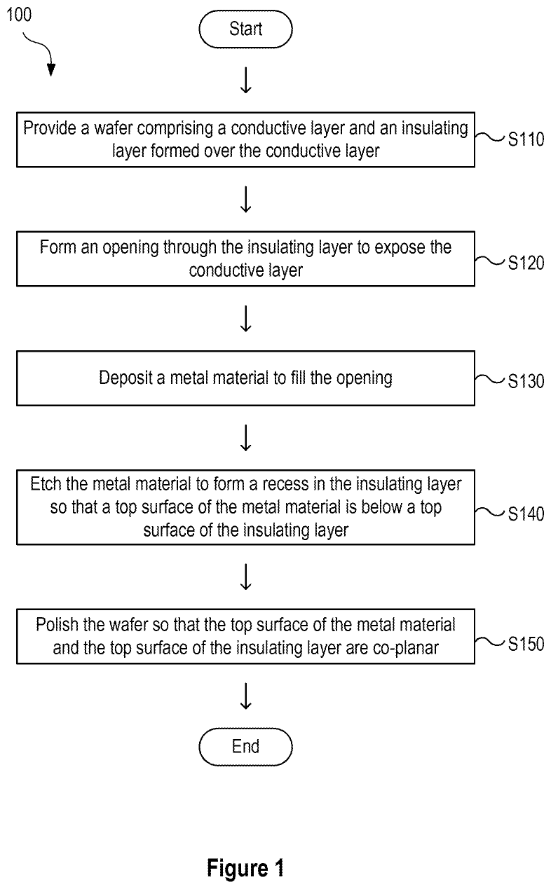

FIG. 1 shows a flow chart of a process 100 of microfabrication, in accordance with some embodiments of the present disclosure. At step S110, a wafer is provided that includes a conductive layer and an insulating layer formed over the conductive layer. At step S120, an opening is formed through the insulating layer to expose the conductive layer. At step S130, a metal material is deposited to fill the opening. At step S140, the metal material is etched to form a recess in the insulating layer so that a top surface of the metal material is below a top surface of the insulating layer. At step S150, the wafer is polished so that the top surface of the metal material and the top surface of the insulating layer are co-planar.

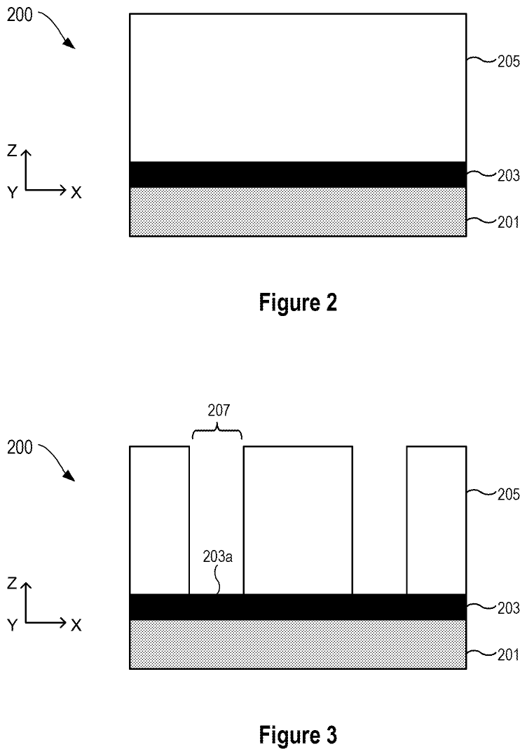

FIGS. 2, 3, 4, 5, 6, 7 and 8 show vertical cross-sectional views of a wafer 200 at various intermediate steps of manufacturing, in accordance with some embodiments of the present disclosure.

As illustrated in FIG. 2, the wafer 200 includes a conductive layer 201 (or a metal layer e.g. tungsten) and an insulating layer 205 (or a dielectric layer e.g. silicon oxide) formed over the conductive layer 201. In some embodiments, the wafer 200 can also include an etch stop layer (ESL) 203 (e.g. silicon nitride, silicon carbonitride, etc.) positioned between the conductive layer 201 and the insulating layer 205.

In FIG. 3, an opening 207 is formed through the insulating layer 205 by a first etch process that stops at a top surface 203a of the ESL 203. The opening 207 may have any shape such as a trench, a slit, a hole, a via, etc. A cross section of the opening 207 in the XY plane can have any shape such as a rectangle, a circle, a hexagon, an ellipse or any irregular shape.

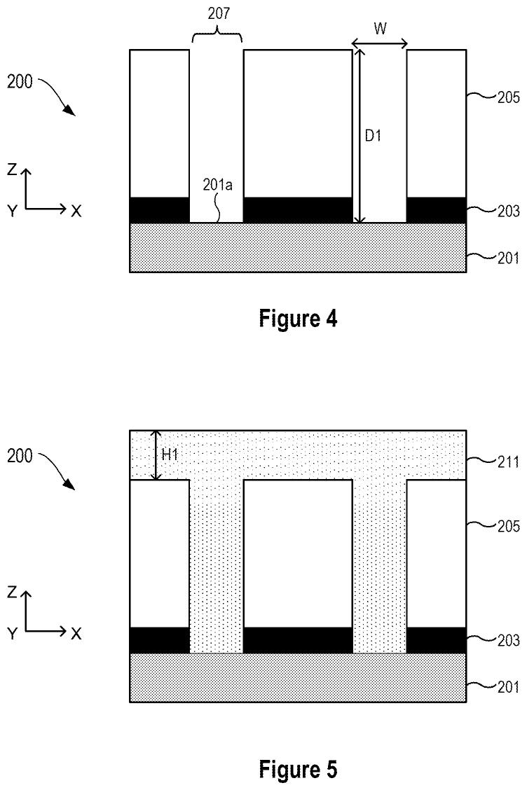

In FIG. 4, a second etch process of the ESL 203 is executed via the opening 207 to expose a top surface 201a of the conductive layer 201. The opening 207 can have a lateral dimension W of 8-20 nm, e.g. 8 nm, 10 nm, 12.5 nm, 15 nm, 17.5 nm, 20 nm or any values therebetween. The lateral dimension W is preferably 7.5-17.5 nm, more preferably 10-15 nm. The opening 207 can have a depth D1 of 30-90 nm, e.g. 30 nm, 40 nm, 50 nm, 60 nm, 70 nm, 80 nm, 90 nm or any values therebetween. The depth D1 is preferably 40-80 nm, more preferably 45-75 nm, more preferably 55-65 nm. The opening 207 can have an aspect ratio, which is defined by D1/W, of 2-20, e.g. 2, 4, 6, 9, 12, 15, 17, 20 or any values therebetween. The aspect ratio is preferably 3-10, more preferably 5-8.

In FIG. 5, a metal material 211 (e.g. ruthenium) is deposited to fill the opening 207. The metal material 211 can overfill the opening 207 and cover the insulating layer 205. An overfilled portion of the metal material 211 can have a height H1 of 5-25 nm, e.g. 5 nm, 9 nm, 13 nm, 17 nm, 21 nm, 25 nm or any values therebetween. The height H1 is preferably 10-20 nm, more preferably about 15 nm.

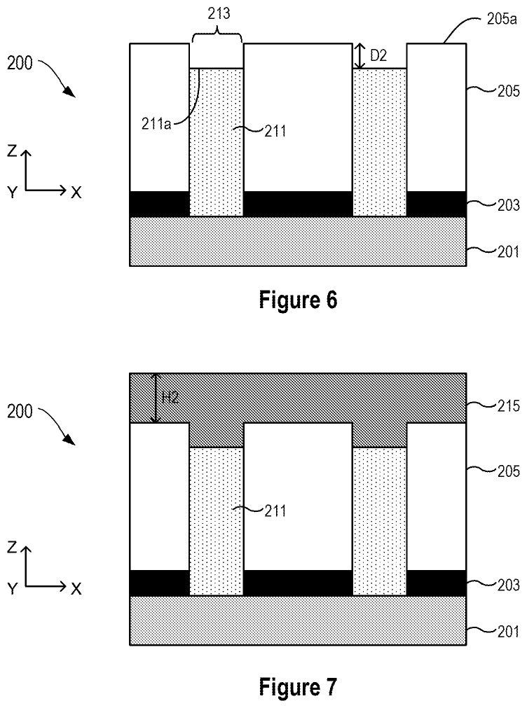

In FIG. 6, the metal material 211 is etched back to form a recess 213 in the insulating layer 205 so that a top surface 211a of the metal material 211 is below a top surface 205a of the insulating layer 205. The recess 213 can have a depth D2 of 1-10 nm, preferably 3-7 nm, preferably 4-6 nm, preferably about 5 nm, or any values therebetween. When the metal material 211 is ruthenium, it can be etched by a plasma containing oxygen and/or chlorine for example.

In FIG. 7, a dielectric material 215 (e.g. silicon oxide) is deposited to fill the recess 213 and cover the insulating layer 205. Preferably, the dielectric material 215 is chosen such that chemical-mechanical polishing (CMP) of the dielectric material 215 is known in the art. Preferably, the dielectric material 215 is softer than the metal material 211 (e.g. ruthenium). The dielectric material 215 can have a height H2 of 15-50 nm, preferably 20-45 nm, preferably 25-40 nm, preferably 30-35 nm, above the top surface 205a of the insulating layer 205.

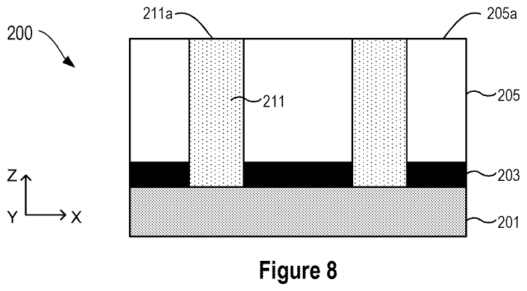

In FIG. 8, a CMP process of the dielectric material 215 (and the insulating layer 205) is executed and stops at the top surface 205a of the insulating layer 205. As a result, the top surface 211a of the metal material 211 and the top surface 205a of the insulating layer 205 are co-planar, i.e. on a same horizontal plane that is parallel to the XY plane. Preferably, the dielectric material 215 includes silicon oxide, silicon nitride or both, and the insulating layer 205 independently includes silicon oxide, silicon nitride or both so that an oxide and/or nitride CMP can be executed. In addition, an endpoint of the CMP process can be determined by monitoring ruthenium signals.

Note that various dimensions and ratios (e.g. W, D1, H1, D2, H2 and D1/W) mentioned herein are merely for illustrative purposes and are not limiting, as a person having ordinary skill in the art would understand. For instance, the height H2 in FIG. 7 can be 200 nm, 500 nm or even more, and techniques herein will still be applicable, nevertheless with a longer CMP duration that may not always be preferred.

Similarly, various materials (e.g. silicon oxide, tungsten, silicon nitride, silicon carbonitride and ruthenium) mentioned herein are merely for illustrative purposes and are not limiting, as a person having ordinary skill in the art would understand. For instance, the conductive layer 201 can include one or more metal materials such as a metal alloy. The conductive layer 201 can include, but is not limited to, tungsten, copper, titanium, ruthenium, niobium, molybdenum, tantalum, aluminum, nickel, chromium, gold, germanium, silver, platinum or any combinations thereof. Preferably, the conductive layer 201 can include tungsten, copper, titanium, ruthenium, tantalum, nickel, chromium, germanium or any combinations thereof. Preferably, the conductive layer 201 can include tungsten, copper, ruthenium or any combinations thereof. Preferably, the conductive layer 201 includes tungsten.

The insulating layer 205 can include one or more dielectric materials. The insulating layer 205 can include, but is not limited to, silicon oxide, silicon nitride, silicon oxynitride, silicon carbonitride, silicon carbon oxynitride, aluminum oxide, titanium oxide, titanium nitride, hafnium oxide, hafnium silicon oxynitride, tantalum pentoxide, zirconium dioxide, boron carbide, boron nitride, hafnium silicate, zirconium silicate, spin-on organic polymeric dielectrics (e.g. polyimide, polynorbornenes, benzocyclobutene, and polytetrafluoroethylene) or any combinations thereof. Preferably, the insulating layer 205 can include silicon oxide, silicon nitride, silicon oxynitride, silicon carbonitride, silicon carbon oxynitride or any combinations thereof. Preferably, the insulating layer 205 can include silicon oxide, silicon nitride or both.

The ESL 203 can include one or more dielectric materials that are configured to be etch-selective to the insulating layer 205. The ESL 203 can include, but is not limited to, silicon oxide, silicon nitride, silicon oxynitride, silicon carbonitride, silicon carbon oxynitride, aluminum oxide, titanium oxide, titanium nitride, hafnium oxide, hafnium silicon oxynitride, tantalum pentoxide, zirconium dioxide, boron carbide, boron nitride, hafnium silicate, zirconium silicate, spin-on organic polymeric dielectrics (e.g. polyimide, polynorbornenes, benzocyclobutene, and polytetrafluoroethylene) or any combinations thereof. Preferably, the ESL 203 can include silicon oxide, silicon nitride, silicon oxynitride, silicon carbonitride, silicon carbon oxynitride or any combinations thereof. Note that while examples of the insulating layer 205 and the ESL 203 may overlap, it should be understood that the insulating layer 205 and the ESL 203 include different materials in order to be etch-selective to each other for the first etch process in FIG. 3. For instance, the insulating layer 205 and the ESL 203 may respectively include silicon oxide and silicon nitride.

The metal material 211 can include one or more metal materials such as a metal alloy. The metal material 211 can include, but is not limited to, ruthenium, tungsten, titanium, niobium, molybdenum, tantalum, aluminum, nickel, chromium, gold, germanium, silver, platinum or any combinations thereof. Preferably, the metal material 211 includes a single metal of ruthenium. Note that the conductive layer 201 and the metal material 211 can include different metals from each other or the same metal(s) as each other. Additionally, the metal material 211 may not include copper.

The dielectric material 215 can include one or more dielectric materials. The dielectric material 215 can include, but is not limited to, silicon oxide, silicon nitride, silicon oxynitride, silicon carbonitride, silicon carbon oxynitride, aluminum oxide, titanium oxide, titanium nitride, hafnium oxide, hafnium silicon oxynitride, tantalum pentoxide, zirconium dioxide, boron carbide, boron nitride, hafnium silicate, zirconium silicate, spin-on organic polymeric dielectrics (e.g. polyimide, polynorbornenes, benzocyclobutene, and polytetrafluoroethylene) or any combinations thereof. Preferably, the dielectric material 215 can include silicon oxide, silicon nitride, silicon oxynitride, silicon carbonitride, silicon carbon oxynitride or any combinations thereof. Note that the insulating layer 205 and the dielectric material 215 can include different dielectrics from each other or the same dielectric(s) as each other. As mentioned earlier, the dielectric material 215 is preferably chosen such that CMP of the dielectric material 215 is known in the art and easy to execute.

FIGS. 2, 3, 4, 5, 6, 7 and 8 above show one example of Ru metallization and wafer planarization involving the deposition and CMP of the dielectric material 215. FIGS. 2, 3, 4, 5, 6 and 8 can show another example of Ru metallization and wafer planarization without involving the deposition or CMP of the dielectric material 215. Going from FIG. 6 to FIG. 8 (without going through FIG. 7), a CMP process of the insulating layer 205 is executed and stops at the top surface 205a of the insulating layer 205. As a result, the top surface 211a of the metal material 211 and the top surface 205a of the insulating layer 205 are co-planar, i.e. on a same horizontal plane that is parallel to the XY plane. Preferably, the insulating layer 205 is chosen such that CMP of the insulating layer 205 is known in the art and easy to execute. For instance, the insulating layer 205 may include silicon oxide, silicon nitride or both so that an oxide and/or nitride CMP is executed.

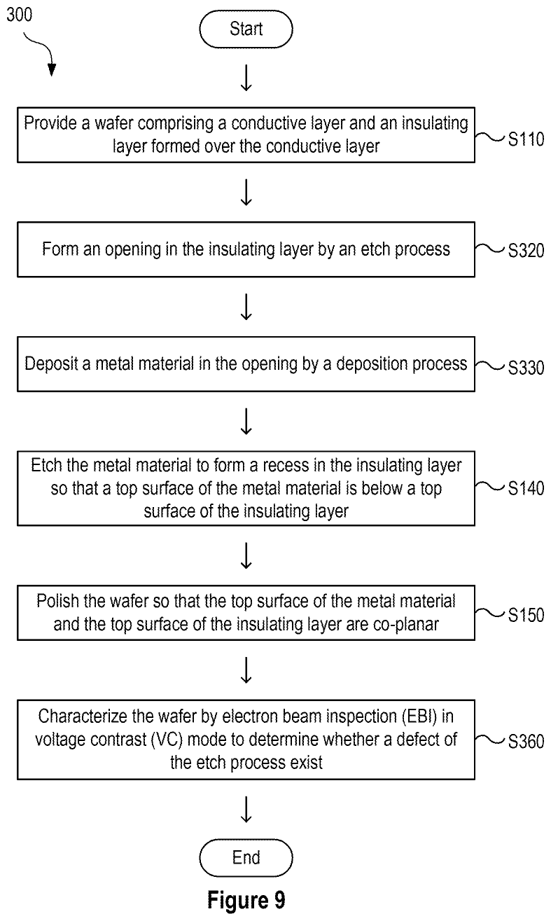

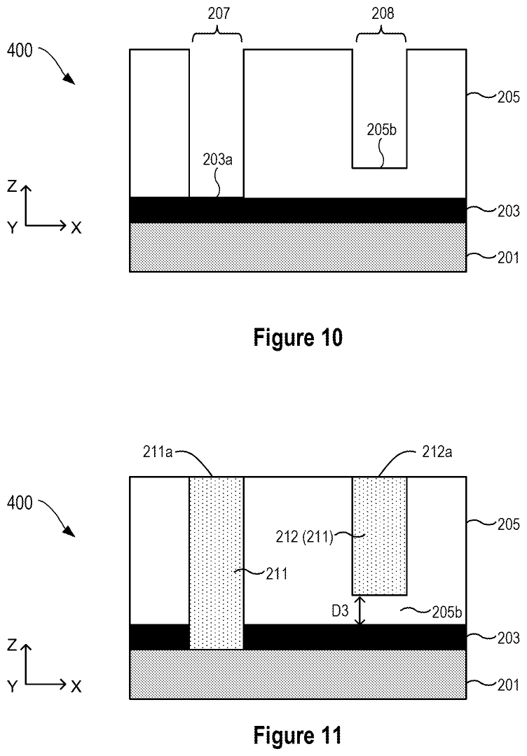

FIG. 9 shows a flow chart of a process 300 of defect detection, and FIGS. 10 and 11 show vertical cross-sectional views of a wafer 400 at various intermediate steps of manufacturing, in accordance with some embodiments of the present disclosure. The embodiment of the process 300 in FIG. 9 is similar to the embodiment of the process 100 in FIG. 1. The embodiments of the wafer 400 in FIGS. 10 and 11 are respectively similar to the embodiments of the wafer 200 in FIGS. 3 and 8. Note that similar or identical components are labeled with similar or identical numerals unless specified otherwise. Descriptions have been provided above and will be omitted for simplicity purposes.

Particularly, at step S320 in FIG. 9, an opening is formed in the insulating layer by an etch process. The opening may or may not be etched all the way through the insulating layer to expose the conductive layer underneath. At step S330, a metal material is deposited in the opening by a deposition process. The metal material may or may not completely fill the opening.

The wafer 400 in FIG. 10 can be obtained by executing the aforementioned first etch process for the wafer 200 in FIG. 2. The first etch process is supposed to etch through the insulating layer 205 to form the opening 207 that exposes the top surface 203a of the ESL 203. However in practice, an opening 208 may be formed in or within the insulating layer 205 and may not expose the top surface 203a of the ESL 203. As a result, the top surface 203a of the ESL 203 may be covered by a residual portion 205b of the insulating layer 205. Additionally, a defect exists when the opening 208 is not etched through the insulating layer 205 by the first etch process. By contrast, the opening 207 is etched through the insulating layer 205 and thus has no defect.

The wafer 400 in FIG. 11 can be obtained by similar processes shown in FIGS. 4, 5, 6, 7 and 8, e.g, etching the ESL 203, depositing the metal material 211, etching the metal material 211 to form the recess 213, depositing the dielectric material 215 to fill the recess 213 and cover the insulating layer 205, and polishing the wafer 400. Alternatively, the wafer 400 in FIG. 11 can be obtained by similar processes shown in FIGS. 4, 5, 6 and 8, e.g, etching the ESL 203, depositing the metal material 211, etching the metal material 211 to form the recess 213, and polishing the wafer 400. Descriptions have been provided above and will be omitted for simplicity purposes.

Accordingly, the opening 208 is filled with the metal material 211 that is separated from the conductive layer 201 by the residual portion 205b of the insulating layer 205. Hereinafter, the metal material 211 in the opening 208 will also be referred to as a metal material 212.

Referring back to FIG. 9, at step S360, the wafer is characterized by electron beam inspection (EBI) in voltage contrast (VC) mode to determine whether a defect of the etch process exists. The defect exists when a VC signal (e.g. brightness) of the opening is below a threshold, and the defect does not exist when the VC signal of the opening is at or above the threshold.

For instance, an EBI VC image of the wafer 400 in FIG. 11 can be generated. While not explicitly shown, the EBI VC image can be a greyscale image containing intensity information, as a person having ordinary skill in the art would understand. For example, background dielectrics (e.g. the insulating layer 205) may show up as dark background areas in the EBI VC image.

In the opening 207, the metal material 211 is in direct contact with the conductive layer 201 and thus forms a continuous conductive path from the conductive layer 201 to the top surface 211a of the metal material 211. Therefore, the opening 207 can show up as a bright shape. As mentioned earlier, the opening 207 may have any shape. When the opening 207 is a hole, the metal material 211 in the opening 207 can show up as a bright spot against the dark background areas in the EBI VC image.

In the opening 208, the metal material 212 is separated from the conductive layer 201 by the residual portion 205b of the insulating layer 205. As a result, a continuous conductive path from the conductive layer 201 to a top surface 212a of the metal material 212 is not formed. Accordingly, when the opening 208 is a hole, the metal material 212 in the opening 208 can show up as a semi-bright or semi-dark spot. That is, the metal material 212 is brighter than the dark background areas and darker than the metal material 211 in the opening 207. Brightness of the metal material 212 depends on a thickness D3 of the residual portion 205b of the insulating layer 205.

In addition to etch defect detection in FIGS. 10 and 11, EBI in the VC mode can also be used for fill defect detection. For example, when the aforementioned first etch process and the aforementioned second etch process do not have defects, the opening 207 exposes the conductive layer 201. However, due to defective deposition, the metal material 211 may not completely fill the opening 207 to form a continuous conductive path from the conductive layer 201 to the top surface 211a of the metal material 211. For instance, an air gap may exist within the metal material 211, or between the conductive layer 201 and the metal material 211. As a result, a semi-bright or semi-dark spot may show up in the EBI VC image.

In the preceding description, specific details have been set forth, such as a particular geometry of a processing system and descriptions of various components and processes used therein. It should be understood, however, that techniques herein may be practiced in other embodiments that depart from these specific details, and that such details are for purposes of explanation and not limitation. Embodiments disclosed herein have been described with reference to the accompanying drawings. Similarly, for purposes of explanation, specific numbers, materials, and configurations have been set forth in order to provide a thorough understanding. Nevertheless, embodiments may be practiced without such specific details. Components having substantially the same functional constructions are denoted by like reference characters, and thus any redundant descriptions may be omitted.

Various techniques have been described as multiple discrete operations to assist in understanding the various embodiments. The order of description should not be construed as to imply that these operations are necessarily order dependent. Indeed, these operations need not be performed in the order of presentation. Operations described may be performed in a different order than the described embodiment. Various additional operations may be performed and/or described operations may be omitted in additional embodiments.

“Substrate” or “wafer” as used herein generically refers to an object being processed in accordance with the invention. The substrate may include any material portion or structure of a device, particularly a semiconductor or other electronics device, and may, for example, be a base substrate structure, such as a semiconductor wafer, reticle, or a layer on or overlying a base substrate structure such as a thin film. Thus, substrate is not limited to any particular base structure, underlying layer or overlying layer, patterned or un-patterned, but rather, is contemplated to include any such layer or base structure, and any combination of layers and/or base structures. The description may reference particular types of substrates, but this is for illustrative purposes only.

The substrate can be any suitable substrate, such as a silicon (Si) substrate, a germanium (Ge) substrate, a silicon-germanium (SiGe) substrate, and/or a silicon-on-insulator (SOI) substrate. The substrate may include a semiconductor material, for example, a Group IV semiconductor, a Group III-V compound semiconductor, or a Group II-VI oxide semiconductor. The Group IV semiconductor may include Si, Ge, or SiGe. The substrate may be a bulk wafer or an epitaxial layer.

Those skilled in the art will also understand that there can be many variations made to the operations of the techniques explained above while still achieving the same objectives of the invention. Such variations are intended to be covered by the scope of this disclosure. As such, the foregoing descriptions of embodiments of the invention are not intended to be limiting. Rather, any limitations to embodiments of the invention are presented in the following claims.

What is claimed is:

1. A method of microfabrication, the method comprising:
providing a wafer comprising a conductive layer and an insulating layer formed over the conductive layer;
forming an opening through the insulating layer to expose the conductive layer;
depositing a metal material to fill the opening;
etching the metal material to form a recess in the insulating layer so that a top surface of the metal material is below a top surface of the insulating layer; and
polishing the wafer so that the top surface of the metal material and the top surface of the insulating layer are co-planar.

2. The method of claim 1, wherein:
the polishing comprises executing a chemical-mechanical polishing (CMP) process of the insulating layer.

3. The method of claim 2, wherein:
the CMP process is configured to stop at the top surface of the metal material.

4. The method of claim 1, further comprising:
depositing a dielectric material to fill the recess and cover the insulating layer.

5. The method of claim 4, wherein:
the polishing comprises executing a chemical-mechanical polishing (CMP) process of the dielectric material and the insulating layer.

6. The method of claim 5, wherein:
the CMP process is configured to stop at the top surface of the metal material.

7. The method of claim 4, wherein:
the dielectric material comprises silicon oxide, silicon nitride, silicon oxynitride, silicon carbonitride, silicon carbon oxynitride or a combination thereof.

8. The method of claim 4, wherein:
the dielectric material and the insulating layer comprise different dielectrics.

9. The method of claim 4, wherein:
the dielectric material and the insulating layer comprise a same dielectric.

10. The method of claim 1, wherein:
the wafer further comprises an etch stop layer (ESL) formed between the conductive layer and the insulating layer.

11. The method of claim 10, further comprising:
executing a first etch process of the insulating layer that stops at the ESL to form the opening through the insulating layer.

12. The method of claim 11, further comprising:
executing a second etch process of the ESL via the opening to expose the conductive layer.

13. The method of claim 1, wherein:
the metal material comprises ruthenium.

14. The method of claim 1, wherein:
the metal material does not comprise copper.

15. The method of claim 1, wherein:
the conductive layer and the metal material comprise different metals.

16. The method of claim 1, wherein:
the insulating layer comprises silicon oxide, silicon nitride, silicon oxynitride, silicon carbonitride, silicon carbon oxynitride or a combination thereof.

17. A method of defect detection, the method comprising:
providing a wafer comprising a conductive layer and an insulating layer formed over the conductive layer;
forming an opening in the insulating layer by an etch process;
depositing a metal material in the opening by a deposition process;
etching the metal material to form a recess in the insulating layer so that a top surface of the metal material is below a top surface of the insulating layer;
polishing the wafer so that the top surface of the metal material and the top surface of the insulating layer are co-planar; and
characterizing the wafer by electron beam inspection (EBI) in voltage contrast (VC) mode to determine whether a defect of the etch process exists, wherein
the defect exists when a VC signal of the opening is below a threshold, and
the defect does not exist when the VC signal of the opening is at or above the threshold.

18. The method of claim 17, wherein:
the VC signal comprises brightness of the metal material in an EBI VC image,
the defect exists when the brightness of the metal material is below a brightness threshold, and
the defect does not exist when the brightness of the metal material is at or above the brightness threshold.

19. The method of claim 17, wherein:
the defect exists when the metal material does not completely fill the opening by the deposition process, and
the defect does not exist when the metal material completely fills the opening by the deposition process.

20. The method of claim 17, wherein:
the defect exists when the opening is not etched through the insulating layer by the etch process, and
the defect does not exist when the opening is etched through the insulating layer by the etch process.
